(19) United States
(12) Patent Application Publication
(10) Pub. No.: US 2026/0271778 A1
(43) Pub. Date: Sep. 10, 2026

(54) FRAME MODULE FOR A SEMICONDUCTOR INTEGRATED CIRCUIT, IC, AS WELL AS A POWER MODULE COMPRISING SUCH A FRAME MODULE AND A METHOD OF MANUFACTURING SUCH A FRAME MODULE

(71) Applicants: NEXPERIA TECHNOLOGY (SHANGHAI) LTD., Shanghai (CN); NEXJPERIA B.V., Nijmegen (NL)

(72) Inventors: Wei GONG, Stockport (GB); Jürgen Hogerl, Munich (DE)

(73) Assignees: NEXPERIA TECHNOLOGY (SHANGHAI) LTD., Shanghai (CN); NEXPERIA B.V., Nijmegen (NL)

(21) Appl. No.: 19/660,163

(22) Filed: Apr. 27, 2026

Related U.S. Application Data
(63) Continuation of application No. PCT/CN2023/128994, filed on Nov. 1, 2023.

(51) Int. Cl. H10W 76/12; H10W 70/20; H10W 72/00; H10W 72/60; H10W 76/01

(52) U.S. Cl. CPC H10W 76/161; H10W 70/20; H10W 72/016; H10W 72/634; H10W 72/647; H10W 76/01

(57) ABSTRACT

A frame module for a semiconductor integrated circuit (IC) including a substrate having the IC, a module to enclose the IC, a Direct Current (DC) supply terminal to provide DC power to the substrate, a DC return terminal to provide a return line for the DC power and an Alternating Current (AC) terminal to provide AC connections to the substrate, the DC supply terminal connects to the substrate at a first end, the DC return terminal connects to the substrate at a second end, the second end being opposite to the first, and the DC return terminal extends above the substrate towards the first end of the substrate, the DC return terminal has at least one opening, located at a part of the DC return terminal that extends above the substrate and the AC terminal connects to the substrate via at least one opening provided in the DC return terminal.

### CROSS-REFERENCE TO RELATED APPLICATIONS

This application is a continuation of PCT/CN2023/128994 filed on Nov. 1, 2023, the contents of which are incorporated by reference herein in their entirety.

### BACKGROUND

### 1. Field of the Disclosure

The present disclosure generally relates to the field of frame modules and, more specifically, to a frame modules that reduce loop inductance.

### 2. Description of the Related Art

Frame modules for wide-bandgap semiconductor chips may play an important role in the integration of these advanced components into electronic systems. Frame modules may also have a significant impact on electromagnetic interference, EMI, and electromagnetic compatibility, EMC, related to those advanced components.

Firstly, frame modules comprise frames which may provide structural support and protection for wide-bandgap semiconductor chips. Constructed from materials like aluminium or copper, they may shield the chips from mechanical stress and damage, enhancing their durability. This physical protection also helps in containing any potential EMI emissions from the chips.

Additionally, frame modules may be designed with EMI/EMC considerations in mind. They often incorporate shielding techniques, such as conductive gaskets, metal enclosures, and grounding provisions, to contain and mitigate EMI emissions. This is especially important in applications where electromagnetic interference can disrupt the performance of nearby electronic components.

Frame modules may also play a role in electrical connectivity, as they include terminals and connectors. Proper grounding and the effective routing of electrical signals within these modules contribute to EMC. By ensuring that the semiconductor chips are electrically well-connected to the module and other components in the system, EMI risks can be further reduced.

Furthermore, EMI/EMC compliance standards may dictate specific requirements for frame modules in certain applications, necessitating features such as EMI filters, ferrites, or specialized shielding materials to meet these standards.

Frame modules may not only provide structural support and protection for wide-bandgap semiconductor chips but may also play a role in addressing EMI and EMC concerns. By incorporating shielding techniques, ensuring proper grounding, and adhering to compliance standards, these modules contribute to the overall performance and electromagnetic compatibility of electronic systems in which they are employed.

There is a need for improved frame module to reduce loop inductance. Loop inductance may pertain to the inductance associated with the electrical pathways or loops within a frame module designed for wide-bandgap semiconductor chips. This loop inductance is an important consideration, particularly in applications involving high-frequency or high-power electronic systems.

Loop inductance arises when electrical current flows in a closed path or loop, which is commonly found within the intricate wiring and interconnections of frame modules supporting wide-bandgap semiconductor chips. High loop inductance can have adverse consequences, including voltage spikes, energy losses, and signal integrity issues. Voltage spikes occur when the current within the loop is abruptly interrupted, leading to electrical noise and interference. Energy losses arise as the loop inductance resists changes in current flow, diminishing system efficiency. In high-frequency applications, loop inductance can cause signal delays and distortions, undermining signal integrity.

### SUMMARY

It would be advantageous to achieve a frame module for a semiconductor integrated circuit, IC, that is arranged in such a way to reduce any loop inductance. It would further be advantageous to achieve a corresponding power module and method of manufacturing such a frame module.

In a first aspect of the present disclosure, there is provided a frame module for a semiconductor integrated circuit, IC.

The frame module comprising:
a substrate comprising said IC;
a frame arranged to circumferentially enclose said IC,
a Direct Current, DC, supply terminal arranged for providing DC power to said substrate, a DC return terminal arranged for providing a return line for said provided DC power and an Alternating Current, AC, terminal arranged for providing AC connections to said substrate;

wherein said DC supply terminal is arranged to connect to said substrate at a first end thereof;

wherein said DC return terminal is arranged to connect to said substrate at a second end thereof, said second end being opposite to said first end, and wherein said DC return terminal extends above said substrate in a direction towards said first end of said substrate, wherein said DC return terminal;

wherein said DC return terminal comprises at least one opening, located at a part of said DC return terminal that extends above said substrate;

wherein said AC terminal is arranged to connect to said substrate via said at least one opening provided in said DC return terminal.

The module as described above may be mounted to the substrate. The substrate comprises the IC, and other electronic components and/or routing mechanisms. Another option is that a base plate is provided, wherein the substrate is mounted to the base plate, and the frame (module) is also mounted to the base plate and circumferentially encloses the substrate having the IC.

The base plate may serve as the foundational component of the frame module, providing structural support for the entire assembly. This typically rigid, substantially flat surface can be designed to securely hold and stabilize the substrate. The substrate may, for example, be a Printed Circuit Board, PCB, or anything alike.

One of the functions of the base plate may be to protect the substrate and the integrated circuit, IC, that is mounted to the substrate. To ensure stability and safeguard the IC, the base plate is typically constructed from durable materials, often including metals that offer robust structural integrity and assist in heat dissipation.

The substrate plays a role by hosting the integrated circuit. This IC is mounted onto the substrate, which often serves as a platform or carrier. Beyond its role as a support structure, the substrate provides electrical connections to the IC. It is typically fashioned as a flat board, frequently square or rectangular in shape, and can be crafted from various materials, such as ceramics, printed circuit boards, PCBs, or semiconductive materials.

The frame, situated atop the base plate, encapsulates and safeguards both the substrate and the IC within. This protective housing often adopts a circular, rectangular, or circumferential design, enveloping the substrate to shield it from external environmental factors and mechanical stresses. The frame may also integrate thermal management features, such as heat sinks, to efficiently dissipate the heat generated by the IC, ensuring its optimal operation.

Finally, the terminal connections are the points where external electrical connections are established with the substrate of the frame module, thereby linking to the IC on the substrate. Within the context described, the Direct Current, DC, supply terminal is responsible for delivering the necessary DC power for the IC's operation and connects to one end of the substrate.

Meanwhile, the DC return terminal serves to establish a return pathway for the DC power. It connects to the substrate at the opposite end and extends upward, and then towards the first end of the substrate. This configuration effectively ensures that the return path for the provided power is securely connected to the substrate.

Additionally, the Alternating Current, AC, terminal provides the necessary connectivity for AC signals that may be required for the IC or other components within the module. Together, these components form a comprehensive frame module that offers structural integrity, protective enclosure, and efficient electrical connectivity for the integrated circuit while facilitating the supply and return of both DC and AC power or signals as needed for the IC's operation.

The inventors have found that it can be beneficial to have at least one opening, located at a part of the DC return terminal that extends above the substrate and that the AC terminal is arranged to connect to the substrate via that at least one opening.

The total design of the frame module reduces loop inductances due to, amongst other, the adjacent DC return terminal. It can be desired to provide a DC return terminal that extends above the substrate in such a way that it covers the substrate as much as possible. In order to provide the necessary AC connection, an opening, or through hole, can be provided in the DC return line such that the AC terminal may protrude the DC return terminal and connect to the substrate.

In an example, the DC return terminal comprises a plurality of openings, located at said part of said DC return terminal that extends above said substrate, wherein said AC terminal is arranged to connect to said substrate via each of said plurality of openings.

It may be beneficial if the width of the part of the DC return terminal that extends over the substrate is just as wide as the substrate itself or is at least 80% as wide as the substrate. This provides a more substantial and consistent electrical connection to, for example, ground across the entire substrate. This enhances the effectiveness of the grounding the integrated circuit and other components, reducing the risk of electrical noise and interference.

The openings can be provided next to one another along the width of the DC return line. The AC terminal can protrude each of these openings such that the AC connections are also provided over the width of the substrate. This improved all kinds of EMC aspects of the frame module.

In a further example, the DC return terminal comprises a plurality of fingers for said connection with said substrate, wherein said plurality of openings are located in between said fingers,
wherein said AC terminal comprises a plurality of fingers arranged to connect to said substrate via each of said plurality of openings in between said fingers of said DC return line.

This would mean that the AC terminal has a plurality of protrusions wherein each of these protrusions are arranged to connect to the substrate.

In a further example, an end of said DC return line, at which said DC return line is arranged to connect to said substrate, is shaped like a comb, wherein an end of said AC terminal, at which said AC terminal is arranged to connect to said substrate, is shaped like a comb.

The end of the DC return line may resemble a comb. The end of the AC terminal may also resemble a comb. These two combs can be placed in such a way that the teeth of one comb are aligned in the gaps or spaces between the teeth of the second comb. In other words, they are facing each other, but the teeth of the first comb fit between the teeth of the second comb without touching them. This creates an interlocking or interlacing arrangement of the combs.

For example, the distance between the fingers in the comb structure may be 1.25 mm. In situations wherein the frame module may be provided by a gel or resin potting, then this distance can be reduced to, for example 500 μm.

In yet another example, the DC return terminal comprises at least five fingers.

In an example, the DC return terminal extends, above said substrate, to said DC supply terminal, such that a lateral distance between said DC return terminal and said DC supply terminal is between 1 mm and 5 mm.

A shorter distance between the DC return terminal and the DC supply terminal effectively minimizes the loop inductance. This can significantly enhance the efficiency and performance of the system, especially in high-frequency applications where minimizing inductance may be of important for signal integrity.

The reduced loop area and minimized distance between terminals can contribute to improved EMC within the system, ensuring that the system operates reliably without causing interference to other nearby electronic devices.

It is further noted that the vertical distance, i.e. the distance between the DC supply terminal and the DC return terminal that extends just above the DC supply terminal, is, typically, in the order of 1 mm-5 mm. This distance may be determined by the height of the IC that is mounted to the substrate.

In a further example, the frame module further comprises
a holder bar arranged to be mounted to said module, wherein, in mounted condition, said holder bar extending over said substrate in a direction perpendicular to said extended direction of said DC return terminal.

The holder bar is introduced to provide a connection for the DC return terminal. The holder bar is to be mounted, in a width direction, to the frame module. The holder bar is then located above the substrate. The DC return terminal will extend under the holder bar towards the DC supply terminal, and will then wrap around the holder bar such that the DC return terminal can be mounted to the holder bar at the top side of the holder bar.

As such, the DC return terminal can be arranged to extend under said holder bar, when said holder bar is mounted to said module, and to wrap around said holder bar such that said DC return frame is arranged to be mounted to said holder bar at a top side of said holder bar.

The DC return terminal can extend under the holder bar towards the DC supply terminal and, when close to the supply terminal, extend upwards and back towards the top side of the holder bar. As such, there is a possibility that there is no directed contact, laterally, between the holder bar and the DC return terminal.

In another example, the DC supply terminal comprises a plurality of fingers arranged for connecting to said substrate.

It is noted that the DC supply terminal can be arranged to connect to said substrate via a press fit contact, that the DC return terminal can be arranged to connect to said substrate via a press fit contact and that the AC terminal can be arranged to connect to said substrate via a press fit contact.

In an example, the frame module further comprises:
a base plate arranged for receiving said substrate, wherein said module is provided on top of said base plate.

In yet another example, the substrate comprises a wide-band semiconductor material.

Wide-bandgap semiconductor materials like silicon carbide, SiC, and gallium nitride, GaN, have found significant applications in various fields. SiC is, for example, used in power electronics for electric vehicles, solar inverters, and RF devices for wireless communication. It may also serve as a substrate material in Light Emitting Diode, LED, manufacturing.

GaN, on the other hand, may be employed in power converters for data centers, laptop and mobile phone chargers, automotive industry, RF amplifiers, and telecommunication infrastructure. These materials contribute to more efficient and high-performance electronic systems across a range of industries.

In a second aspect of the present disclosure, there is provided a power module comprising a frame module in accordance with any of the previous examples.

It is noted that the advantages as explained with reference to the first aspect of the present disclosure, being the frame module, are also applicable to the aspects of the second aspect of the present disclosure, being the power module comprising such a frame module.

In a third aspect of the present disclosure, there is provided a method of manufacturing a frame module in accordance with any of the previous examples, wherein said method comprises the steps of:
providing said substrate;
providing said module such that said module circumferentially encloses said IC;
mounting said DC supply terminal, said DC return terminal and said AC terminal to said module, such that said DC supply terminal, said DC return terminal and said AC terminal connect to said substrate.

In an example, the method further comprises the step of
providing a gel or resin potting on top of said substrate.

On top of the above, it is noted that the DC return terminal may not extend fully from one side of the frame module to the opposing side of the frame module. This seen in a width direction. This allows some room on the substrate at the edges thereof. That is, room where components may be placed that are a bit higher compared to the IC that is placed on the IC. This is made possible as, at those locations at the edge of the substrate, there is no DC supply terminal covering the substrate. These locations may be used for electrical purposes, i.e., to improve any desired electrical characteristics associated with the substrate. Another option is to include Electromagnetic Compatibility components, like snubbers, that might need capacitors to be mounted on the substrate.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

The above and other aspects of the disclosure will be apparent from and elucidated with reference to the examples described hereinafter.

### BRIEF DESCRIPTION OF THE DRAWINGS

FIGS. 1a, 1b and 1c disclose cross sectional views of a part of a frame module in accordance with the present disclosure.

FIG. 2 discloses a three-dimensional view of a part of a frame module in accordance with the present disclosure.

FIG. 3a discloses an assembled frame module in accordance with the present disclosure.

FIG. 3b discloses a frame module in accordance with the present disclosure.

FIG. 4 discloses an example of a method in accordance with the present disclosure.

### DETAILED DESCRIPTION

A more detailed description is made with reference to particular examples, some of which are illustrated in the appended drawings, such that the manner in which the features of the present disclosure can be understood in more detail. It is noted that the drawings only illustrate typical examples and are therefore not to be considered to limit the scope of the subject matter of the claims. The drawings are incorporated for facilitating an understanding of the disclosure and are thus not necessarily drawn to scale. Advantages of the subject matter as claimed will become apparent to those skilled in the art upon reading the description in conjunction with the accompanying drawings.

The ensuing description above provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing a preferred exemplary embodiment of the disclosure, it being understood that various changes can be made in the function and arrangement of elements, including combinations of features from different embodiments, without departing from the scope of the disclosure.

Unless the context clearly requires otherwise, throughout the description and the claims, the words “comprise” “comprising” and the like are to be construed in an inclusive sense, as opposed to an exclusive or exhaustive sense; that is to say, in the sense of “including, but not limited to.” As used herein, the terms “connected” “coupled” or any variant thereof means any connection or coupling, either direct or indirect, between two or more elements; the coupling or connection between the elements can be physical, logical, electromagnetic, or a combination thereof. Additionally, the words “herein” “above” “below” and words of similar import, when used in this application, refer to this application as a whole and not to any particular portions of this application. Where the context permits, words in the Detailed Description using the singular or plural number may also include the plural or singular number respectively. The word “or” in reference to a list of two or more items, covers all of the following interpretations of the word: any of the items in the list, all of the items in the list, and any combination of the items in the list.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

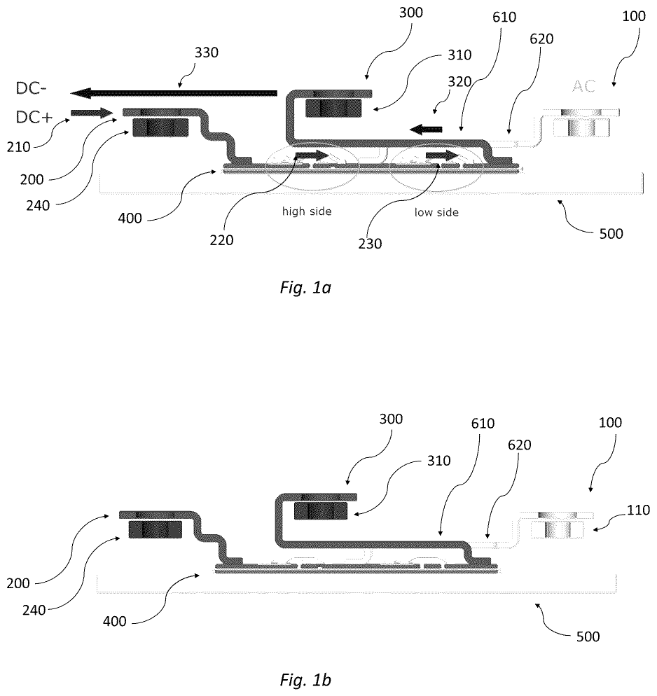

FIGS. 1a, 1b and 1c disclose cross sectional views of a part of a frame module in accordance with the present disclosure.

Stray parasitic inductance within power modules, particularly in third-generation semiconductors like silicon carbide, SiC, and gallium nitride, GaN, chips, may pose a threat by leading to voltage overshoot. The rapid switching speeds of these advanced semiconductors amplify their sensitivity to parasitic inductance.

The cause for this parasitic inductance in power modules may lay with a variety of components, including copper traces, die top connections, which may include bonding wires, clips, ribbons, and the like, and even terminal connections. All these components may be related to the substrate.

When current flows through these components, the current may encounter resistance due to the inherent inductance, resulting in voltage spikes or overshoots. This phenomenon can have adverse consequences, such as damaging sensitive electronic components, reducing overall system efficiency, and potentially causing malfunctions or failures.

Managing stray parasitic inductance has become a consideration in the design and engineering of power modules, especially when incorporating high-speed switching semiconductors like SiC and GaN. Strategies like careful layout design, optimized component placement, and the use of snubber circuits or magnetic shielding are employed to mitigate these hazards and ensure the reliable operation of power electronics systems. Present disclosure is directed to improving the commutation loop stray inductance with the topology of the terminals used within the frame module.

FIGS. 1a, 1b and 1c shows a typical example. Here, a side view of a comb structure (610, 620) arrangement between the DC return (indicated in the figures and hereafter also referred to as “DC−”) terminal (300) and the AC terminal (100) is disclosed. The DC return terminal (300) is located above the substrate (400) and may be considered as an adjacent plane to the substrate (400).

In FIG. 1a, a substrate (400) is mounted to the base plate (500). The arrows (210, 220, 230) indicate the general direction of the current flowing from the DC supply terminal (indicated in the figures and hereafter also referred to as “DC+”) terminal (100) through the substrate (400). The DC return terminal (300) and the AC terminal (100) have ends that are shaped as a comb (indicated in the figures as 610 and 620, respectively), and are arranged in such a way that the teeth of one comb (610 or 620) are aligned in the gaps or spaces between the teeth of the other comb (620 or 610). In other words, they are facing each other, but the teeth of the first comb fit between the teeth of the second comb without touching them. This creates an interlocking or interlacing arrangement of the combs.

The teeth do not physically contact with one another so that there is no risk to a short circuit between the DC side and the AC side of the circuit.

It is further shown that the DC return terminal (300) extends substantially over the top side of the substrate (400). In fact, the DC return terminal (300) extends underneath the actual connection point (310), i.e. the point at which the DC return terminal connects to the frame module such that the current flows in an opposite direction (see arrow 320). Once this connection point has surpassed, the DC return terminal (300) deflects upwards and back to its original direction. The DC return terminal (300) thus makes some sort of C-shape (or U-bend shape) at one of its ends, thereby increasing its coverage area of the substrate (400). At the top side of the C-shape, the DC return terminal (300) may be mounted to the frame module through connection point (310).

FIG. 1a shows the current flowing from the DC supply (DC+) terminal to the DC return (DC−) terminal. As shown in the direction of the arrow (210), the current flows from the DC+ terminal—at the side coupled to connection port (240)—to the substrate (400). The current then travels from one end of the substrate to another end of said substrate in a direction perpendicular to the base plate (500). Upon reaching the other end of the substrate, the current flows onto the DC− terminal (300) in the direction of the arrow (320). The current then terminates the frame module where the DC− terminal is coupled to connection port (310). The substrate (400) can also comprise of separate sections, with wires connecting each portion of the substrate. According to an embodiment illustrated in FIG. 1a, there substrate (400) comprises sections which are connected with wires, where the sections connected by wires closest to the DC+ terminal (200) is referred to as “high side”, and the sections connected by wires closest to the DC− (300) and AC (100) terminals is referred to as “low side”.

FIG. 1b illustrates a simplified version of the frame module of FIG. 1a.

FIG. 1c illustrates how the AC terminal (100) is connected to the substrate (400). The comb (620) of the AC terminal (100) overlaps the comb (610) of the DC− terminal.

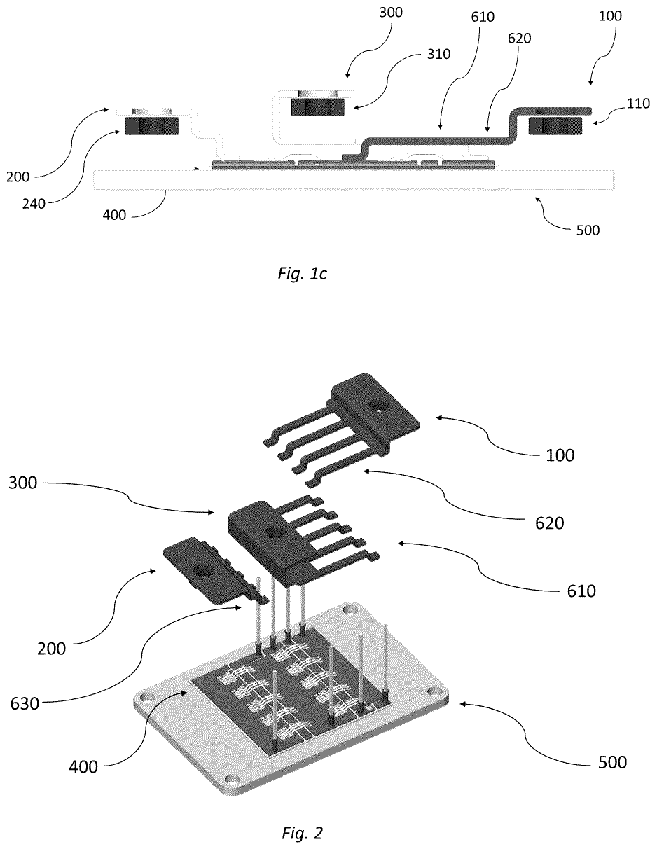

FIG. 2 discloses a three-dimensional view of a part of a frame module in accordance with the present disclosure.

Here, the DC supply terminal (200), the DC return terminal (300) as well as the AC terminal (100) all have a comb shaped end face for connection to the substrate. The AC terminal (100) has four fingers (620), and the DC return terminal (300) has five fingers (610), and the DC supply terminal (200) also has five fingers (630).

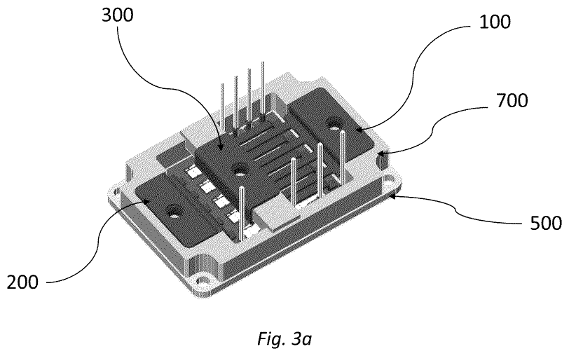

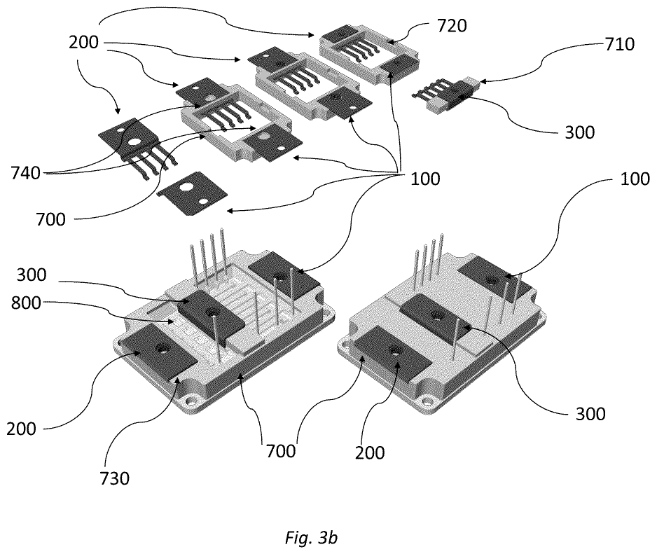

FIG. 3a discloses an assembled frame module (700) in accordance with the present disclosure, and FIG. 3b discloses an assembled frame module in accordance with the present disclosure.

It is noted that any of the DC return terminal (300), the DC supply terminal (200) and the AC terminal (100) may be integrated with the module (700).

FIG. 3a discloses another embodiment according to the present disclosure. In this embodiment, the frame module (700) is fabricated with indented (or recessed) portions (730) configured to receive to secure a portion of the terminals (100, 200, 300) to at least one part of the frame module (700,710). This ‘outer’ portion of the frame module is also called the frame. This allows for greater stability of the terminals onto the frame module. Preferably, the frame module (700) is fabricated by molding process together with AC terminal (100) and DC supply terminal (200) in place, so that the AC and DC terminals are integrated into the frame as a whole (see FIG. 3a). Examples of such integration is the creation of a bridge (740) for the AC and DC terminals.

According to another embodiment of the present disclosure, the frame module (700) can comprise of multiple parts. As shown in FIG. 3a, the frame module (700) can comprise of an outer frame (700) and a separate (and removable) holder bar (710). While the AC and DC terminals can be placed onto or integrated into the frame, the DC return terminal (300) can be placed on the holder bar (710). While only the configuration of the holder bar (710) being surrounded on three-sides by the DC return terminal (300) is shown (i.e., the DC return terminal (300) wraps around said holder bar (710) in a C-shape or U-shape form), other configurations may be possible to improve the stability of the DC return terminal (300) in the frame (700). For example, the DC return terminal (300) can also extend to a fourth side or extend outward away from the surfaces of the holder bar (710).

In order to facilitate placement of the holder bar into the frame (700) of the frame module (700), the frame module (700) comprises a locking mechanism (720) on the surfaces of the frame (700) configured to (mechanically) couple with the holder bar (710). For example, at least one inner wall of the frame (700, facing the area of the frame module comprising the electronic components), can comprise a locking mechanism (720, such as an opening or steps) configured to receive at least one side of the holder bar (710). Preferably, more than one inner wall comprises said locking mechanism. While the same locking mechanism could be employed on a plurality of inner walls, different locking mechanisms could be employed in order to improve the stability of the DC return terminal (300) coupled to the frame (700).

According to another embodiment of the present disclosure, the frame of the frame module (700) comprises openings in the indented (or recessed) portions. For example, the frame (700) may have an opening between said frame (700) and the bridge (740), creating said opening. This allows for the terminals (100, 200) to slide from one side of the frame module (700) to another, using parts of the frame (700) as stabilizers.

According to another embodiment of the present disclosure, once the holder bar (710) is coupled to the frame of the frame module (700), a cover (800) can be inserted in the openings between the holder bar (710) and the frame (700) in order to seal the electronic components on the base plate (300).

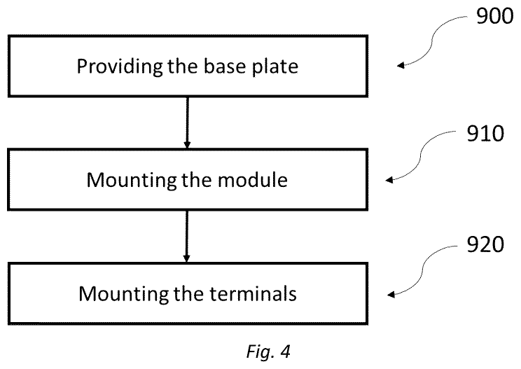

FIG. 4 discloses an example of a method in accordance with the present disclosure.

The method is directed to the of manufacturing a frame module in accordance with any previous example.

The method comprises the steps of:
providing (900) said base plate and mounting said substrate to said base plate;
mounting (910) said module to said base plate such that said module circumferentially encloses said substrate;
mounting (920) said DC supply terminal, said DC return terminal and said AC terminal to said module, such that said DC supply terminal, said DC return terminal and said AC terminal connect to said substrate.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope thereof.

1. A frame module for a semiconductor integrated circuit (IC), the frame module comprising:
a substrate comprising the IC;
a frame arranged to circumferentially enclose the IC;
a Direct Current (DC) supply terminal arranged to provide DC power to the substrate, a DC return terminal arranged to provide a return line for the provided DC power and an Alternating Current (AC) terminal arranged to provide AC connections to the substrate;
wherein the DC supply terminal is arranged to connect to the substrate at a first end thereof;
wherein the DC return terminal is arranged to connect to the substrate at a second end thereof, the second end being opposite to the first end, and wherein the DC return terminal extends above the substrate in a direction towards the first end of the substrate;
wherein the DC return terminal comprises at least one opening, located at a part of the DC return terminal that extends above the substrate; and
wherein the AC terminal is arranged to connect to the substrate via the at least one opening provided in the DC return terminal.

2. The frame module in accordance with claim 1, wherein the DC return terminal comprises a plurality of openings, located at the part of the DC return terminal that extends above the substrate, and
wherein the AC terminal is arranged to connect to the substrate via each of the plurality of openings.

3. The frame module in accordance with claim 2, wherein the DC return terminal comprises a plurality of fingers for the connection with the substrate, wherein the plurality of openings are located in between the fingers, and
wherein the AC terminal comprises a plurality of fingers arranged to connect to the substrate via each of the plurality of openings in between the fingers of the DC return line.

4. The frame module in accordance with claim 3, wherein the DC return line has an end that is shaped like a comb, at which the DC return line is arranged to connect to the substrate, and
wherein the AC terminal has an end that is shaped like a comb, at which the AC terminal is arranged to connect to the substrate.

5. The frame module in accordance with claim 3, wherein the DC return terminal comprises at least five fingers.

6. The frame module in accordance with claim 1, wherein the DC return terminal extends, above the substrate, to the DC supply terminal, so that a lateral distance between the DC return terminal and the DC supply terminal is between 1 mm-5 mm.

7. The frame module in accordance with claim 1, wherein the frame module further comprises
a holder bar arranged to be mounted to the frame, wherein, in mounted condition, the holder bar extends over the substrate in a direction perpendicular to the extended direction of the DC return terminal.

8. The frame module in accordance with claim 7, wherein the DC return frame is arranged to extend under the holder bar, when the holder bar is mounted to the frame, and to wrap around the holder bar so that the DC return frame is arranged to be mounted to the holder bar at a top side of the holder bar.

9. The frame module in accordance with claim 1, wherein the DC supply terminal comprises a plurality of fingers arranged to connect to the substrate.

10. The frame module in accordance with claim 1, wherein any of the:
the DC supply terminal is arranged to connect to the substrate via a press fit contact;
the DC return terminal is arranged to connect to the substrate via a press fit contact;
the AC terminal is arranged to connect to the substrate via a press fit contact.

11. The frame module in accordance with claim 1, wherein the frame module further comprises:
a base plate arranged to receive the substrate, and wherein the module is provided on top of the base plate.

12. The frame module in accordance with claim 11, wherein the substrate comprises a wide-band semiconductor material.

13. The power module comprising a frame module in accordance with claim 1.

14. The method of manufacturing a frame module in accordance with claim 11, wherein the method comprises the steps of:
providing the substrate;
providing the frame so that the frame module circumferentially encloses the IC; and
mounting the DC supply terminal, the DC return terminal and the AC terminal to the frame, so that the DC supply terminal, the DC return terminal and the AC terminal connect to the substrate.

15. The method of manufacturing in accordance with claim 14, wherein the method further comprises the step of:
providing a gel or resin potting on top of the substrate.

16. The frame module in accordance with claim 2, wherein the frame module further comprises:
a base plate arranged to receive the substrate, and wherein the module is provided on top of the base plate.

17. The power module comprising a frame module in accordance with claim 2.

18. The method of manufacturing a frame module in accordance with claim 12, wherein the method comprises the steps of:
providing the substrate;
providing the frame so that the frame module circumferentially encloses the IC;
mounting the DC supply terminal, the DC return terminal and the AC terminal to the frame, so that the DC supply terminal, the DC return terminal and the AC terminal connect to the substrate.
